(19) United States
(12) Patent Application Publication
(10) Pub. No.: US 2020/0293706 A1
(43) Pub. Date: Sep. 17, 2020

(54) Method and System for Modelling a Pipe Network

(71) Applicant: Minimax Viking Research & Development GmbH, Bad Oldesloe (DE)

(72) Inventors: Alina Vergil, Bad Oldesloe (DE); Gudrun Fay, Bad Oldesloe (DE)

(21) Appl. No.: 16/706,221

(22) Filed: Dec. 6, 2019

(30) Foreign Application Priority Data
Dec. 7, 2018 (DE) 10 2018 131 307.1
Dec. 6, 2019 (DE) 10 2019 133 414.4

(51) Int. Cl. G06F 30/28; G05D 7/06

(52) U.S. Cl. CPC G06F 30/28; G05D 7/0676

(57) ABSTRACT

The invention relates to a method and a system for modeling a pipe network for conveying an extinguishing fluid, which comprises the following steps: (i) approximating at least one operating parameter of the pipe network for each of a plurality of pipes of the pipe network based on at least one fluid parameter within the pipe network, (ii) determining at least one fluid value of the extinguishing fluid based on the approximating for each of the plurality of pipes, (iii) comparing at least one fluid value with a target value, (iv) adjusting the initial pipe geometry for at least one pipe from the plurality of pipes based on the comparing, and (v) adjusting the at least one operating parameter of the pipe network, wherein the method comprises multiple iterations of the steps i) to v).

### PRIORITY CLAIM AND INCORPORATION BY REFERENCE

This application claims priority to German Application No. 10 2018 131 307.1 filed Dec. 7, 2018, and German Application No. 10 2019 133 414.4 filed Dec. 6, 2019, each of which is incorporated by reference in its entirety.

### TECHNICAL FIELD

The present invention relates to a method for modeling a pipe network, in particular, a nozzle pipe network, for conveying an extinguishing fluid, in particular a multiphase extinguishing fluid and/or a multiphase multicomponent extinguishing fluid, a corresponding system for modeling, and a computer program with program code means for the computer implementation of the method.

### BACKGROUND AND SUMMARY OF THE INVENTION

The present invention relates, in particular, to pipe networks for use in extinguishing systems, in particular, fire extinguishing systems, in which an extinguishing fluid is released through a nozzle. These extinguishing systems can be used to fight and/or contain fires in a plurality of different areas, such as electric fires, wood fires or the like.

Depending on the application area, different extinguishing fluids can be used, which must be selected differently depending on the characteristics of the materials to be extinguished. For example, water or water with additives cannot be used as extinguishing fluid in certain cases, such as, for example, metal fires.

In such cases, other extinguishing fluids are used. While some of these extinguishing fluids can comprise a single-phase system, i.e. either liquid or gaseous, among these extinguishing fluids, there are also those that comprise a multiphase system. These extinguishing fluids are referred to below as multiphase extinguishing fluids. In particular, two-phase extinguishing fluids, i.e. extinguishing fluids that have two phases, are considered below.

In order to ensure efficient and rapid firefighting and/or fire containment by extinguishing systems, it is necessary that the extinguishing fluid of their pipe networks is conveyed at the required speed and pressure from the extinguishing fluid supply to the extinguishing fluid outlets—in the case of nozzle extinguishing systems, the nozzles. To do this, the individual pipes must be manufactured depending on their conveyance, their number of junctions and outlets, as well as other, similar factors. Particular care must be taken to ensure that the individual pipes have a suitable pipe geometry, in particular a suitable inner diameter, which can be used to ensure that the necessary operating pressure of the system is maintained and that the extinguishing fluid with the correct pressure is transported to the extinguishing fluid outlets and exits from them. The selection of the appropriate pipe geometry for each individual pipe of the pipe network is therefore of fundamental importance for the functionality of the extinguishing system.

From prior art, different possibilities are known to appropriately select the pipe geometry of the individual pipes. One possibility is the manual or computer-aided estimating of the pipe geometries, in particular, the dimension of the individual pipes characterized by a corresponding nominal width for each of the pipes, taking the fluid dynamics through the corresponding pipes into account. Here, hydraulic calculations can be used to determine which values the operating pressure and/or the inlet and/or outlet pressure assume for a certain amount of fluid through a pipe of a certain geometry.

In this case, in accordance with the prior art, each pipe is considered independently from the others. This means that the pipe network as a whole cannot be optimized and, thus, results in unnecessary pressure losses, inaccuracies and unsatisfactory operating pressures of certain pipe networks.

Furthermore, the methods in accordance with the prior art only allow to determine the behavior of single-phase extinguishing fluids or single-component extinguishing fluids accurately. In the case of two- or multiphase extinguishing fluids and/or two- or multicomponent extinguishing fluids, in particular in the case of multiphase multicomponent extinguishing fluids, the methods for determining the pipe geometry of the individual pipes in accordance with the prior art are inherently inaccurate, wherein an improvement of the accuracy requires a high computational effort and a lot of time.

In view of the above, it is an object of the present invention to provide a method and a corresponding system that allows a more precise and faster estimation of the pipe geometry of the individual pipes within the pipe network, wherein this estimation takes into account the flow behavior of an extinguishing liquid flowing through the pipe network, in particular, a two-phase extinguishing fluid, and even more particularly, a two-phase two-component extinguishing fluid.

This object is achieved according to the invention by means of a method comprising the steps of:
i) approximating at least one operating parameter of the pipe network and an initial pipe geometry for each of a plurality of pipes of the pipe network based on at least one fluid parameter within the pipe network,
ii) determining at least one fluid value of the extinguishing fluid based on the approximating for each of the plurality of pipes,
iii) comparing at least one fluid value with a target value,
iv) adjusting the initial pipe geometry for at least one pipe from the plurality of pipes based on the comparing, and
v) adjusting at least one operating parameter of the pipe network, wherein the method comprises multiple iterations of the steps i) to v).

A pipe network according to the invention is understood as a network of a plurality of pipes that are connected to each other via corresponding connection pieces. This type of pipe networks is used, in particular, in the field of fire protection, meaning in extinguishing systems, in particular, special extinguishing systems.

In a preferred embodiment, in particular, the pipe network according to the invention is a nozzle pipe network. Such pipe networks typically comprise a plurality of nozzles that serve as extinguishing fluid outlets from the pipe network. Through these nozzles, the extinguishing fluid is released at a predetermined pressure and at a predetermined speed. As mentioned above, the release of the extinguishing fluid can be guaranteed at a predetermined pressure and at a predetermined speed if the pipe network is capable of ensuring a certain operating pressure.

In some embodiments, the pipe network may also be a pipe network for dispensing an extinguishing fluid, which is output from the extinguishing fluid outlets as a fast-expanding foam. Within the pipe network, this extinguishing fluid is in a liquid state and is then output from the pipe network by corresponding foam outlets. The extinguishing foam originates from these outlets. In such a case, the extinguishing fluid within the pipe network may also be regarded as a multiphase multicomponent extinguishing fluid since these are usually gas-detergent-water mixtures that correspondingly contain several components—i.e. gas, in particular, air, detergent and water—wherein these several components are present in a plurality of phases, in particular liquid/gaseous and/or liquid/gaseous/solid. Since the mixtures within the pipe network are dispensed in some form of “pre-foam”, and converted to the completely frothy foam only upon release from the pipe network, the pipe geometry of the pipes of the pipe network may also be approximated and/or adjusted for such an extinguishing fluid using the present invention.

An operating parameter of the pipe network is understood, in particular, as a parameter that specifies a characteristic of the pipe network in operation. In some embodiments, the operating parameter is, in particular, the operating pressure of the pipe network.

An approximating of the operating parameter is an estimation of an operating parameter of the entire pipe network based on the expected pipe network geometry and additional specifications. The estimation may be performed here, for example, on the basis of empirical values.

An approximation of an initial pipe geometry is understood as an estimation of the initial pipe geometry of each individual pipe of the pipe network. This means that, while each pipe is estimated individually, the other pipes are taken into account for said approximation. The length and distribution of the pipes are specified here by the region to be protected. In particular, estimating the initial pipe geometry encompasses estimating an initial pipe diameter.

At the beginning of the modeling process, the pipe network is initially defined and that being based on an estimate that takes into account one or a plurality of fluid parameters for the extinguishing fluid within the pipe network. These fluid parameters may include, for example, the mass flow, as well as the minimum and maximum speed within the corresponding pipe. Based on these fluid parameters, for example, the maximum and minimum nominal width may be approximated for the pipes of the pipe network. This approximation is also referred to as determining in the context of the invention since the approximation is sufficiently precise to actually work with the values.

In contrast to the prior art, the method according to the invention thus assumes a holistic view of the pipe network rather than considering the different pipes (or pipe segments) independently.

Preferably, the geometries of all pipes of the network are determined. However, it is also possible to determine only a part of the pipes. In this case, a diameter is preferably assigned to the pipes not to be determined and the fluid characteristics through these pipes are accordingly integrated into the approximation of the pipe under consideration (i.e. the one to be approximated).

The approximation may be performed automatically by the system, for example, if the system has access to a database with the empirical values. Additionally or alternatively, the approximation may also be performed manually. In this case, the user could enter his/her own estimated values into the system.

Following the estimation of the initial pipe geometry, at least one fluid value of the extinguishing fluid, such as the pressure drop along the pipe and/or pipe network, is determined. This may occur, in particular, on the basis of the density and/or the gas content of the extinguishing fluid or the like. This determination is performed here for each pipe and/or pipe segment one after the other, starting with the pipe that is closest to the extinguishing fluid supply. The fluid values determined for the previously determined pipes are passed on for the calculation from pipe to pipe.

In order to determine whether a suitable pipe geometry has been selected for each pipe, the fluid values determined in this manner are then compared with corresponding target values. These target values are specified, for example, by the requirements for the extinguishing system. As an example, the pressure within the pipe shall be mentioned. This pressure may be compared with a target value which is specified by the minimum nozzle pressure of at least one nozzle on the pipe network. The target values for the comparison may preferably be read from a database.

On the basis of this comparison of at least one fluid value with the corresponding target value, the initial pipe geometry of the pipe considered at the point in time is then adjusted. An adjustment of the initial pipe geometry is understood as maintaining the initial pipe geometry in the case of the fluid value not deviating from the target value. In that context, a deviation from the target value is understood, in particular, as a deviation by a value that is greater than a predetermined tolerance threshold.

On the other hand, an adjustment according to the invention may also correspond, should it be determined during this comparison that the fluid value deviates from the target value by more than the tolerance range, to a modification of the initial pipe geometry of the corresponding pipe, wherein, in this case, the adjustment entails a re-estimation of the pipe geometry based on the comparison. Here, this process may be carried out for all or part of the pipes of the network so that at the end of the passage the fluid values for the extinguishing fluid within all pipes are within the target range. The operating parameter of the pipe network is then redetermined and the next iteration is performed with the adjusted operating parameter. Hereby, the pipe geometry adjusted during the previous iteration for the corresponding pipes is used as the initial pipe geometry for these pipes.

This iterative determination is terminated when the values for the operating parameter converge at an appropriate target value. In this case, it is assumed that a suitable pipe geometry has been found for the pipes of the nozzle pipe network.

In a preferred embodiment, during each iteration, each of the pipes of the pipe network is approximated and adjusted one after the other along the flow direction of the extinguishing fluid by performing the above-mentioned steps i to iv.

A nozzle pipe network according to the invention may be used, in particular, in a fire extinguishing system. Here, the nozzle pipe network serves to convey an extinguishing fluid from an extinguishing fluid supply to one or a plurality of extinguishing fluid outlets, usually nozzles. The flow direction of the extinguishing fluid, also called the fluid direction, corresponds to the direction from the extinguishing fluid supply to the extinguishing fluid outlets. This direction specifies the order in which each of the individual pipes, in particular each of the individual pipe geometries, is determined. This means that the pipe geometries, in particular the nominal widths of the pipes, are processed in the forward direction of the fluid flow one after the other, starting with the pipe that is closest to the extinguishing fluid supply and ending with the pipe that flows into the extinguishing fluid outlet. Here, the effects of possible junctions, extinguishing fluid outlets and/or pipe fittings without extinguishing fluid throughput are included in the determination.

The method is performed in such a way that a pipe is initially approximated and adjusted. When this pipe is completed, the subsequent pipe follows. The resulting fluid parameters are also passed on to the next pipe. Since the pipe geometries may be determined based on each other, this method allows for a systematic structuring of the pipe network from its starting point (the extinguishing fluid supply) to its end. This encompasses performing enough iterations until the values of the operating parameter converge at a target value.

In accordance with a further preferred embodiment, the method of the invention further comprises a specifying of at least one pipe geometry limit value for at least one pipe geometry parameter of each of the pipes from the plurality of pipes, a comparison of the pipe geometry limit with a value of the pipe geometry approximated for the corresponding pipe geometry parameter for the corresponding pipe geometry, and, if it is determined that the value exceeds and/or undercuts the limit value, aborting the adjustment of the pipe geometry for the corresponding pipe.

In some embodiments, a limit value may be specified for the value of at least one parameter of the pipe geometry of the individual pipes. In this context, a parameter of the pipe geometry is understood as corresponding to all measurement parameters of the pipe geometry. In one embodiment, the parameter of the pipe geometry particularly comprises a nominal width of the pipes. The limit values may be specified on the basis of certain conditions and, in particular, specifications regarding pressure, speed or the like of the extinguishing fluid, as well as on the basis of other factors, such as the transitions between the pipes. Here, not all specifications and factors are mandatorily required; depending on the case at hand, different specifications and/or factors may make the specification possible.

Subsequently, the parameter values approximated as described above—for example via a hydraulic calculation—are compared with the limit value and, if the limit value deviates from the limit value upwards or downwards, meaning when the limit value is exceeded or undercut, the adjustment of this particular pipe (for the time being) is aborted.

In another preferred embodiment, the method comprises adjusting the pipe geometry, meaning the value of the pipe geometry, of another pipe, which is arranged in the flow direction of the extinguishing fluid in front of or behind the corresponding pipe if it is determined that the value exceeds and/or undercuts the limit value.

In some embodiments, appropriate limit values for the pipe geometry values may be selected, such as a minimum or maximum nominal width for each pipe. If the approximation of the pipe geometry values results in the approximated value being above or below the previously specified limit value accordingly, the estimated nominal width is not assigned to this pipe. In order to nevertheless make it possible to implement the corresponding values for the operating parameter(s) in the pipe network, the nominal width of the pipe which has just been estimated is not changed but the geometry of one of the surrounding pipes is changed instead.

In that context, the term surrounding pipes is to be understood in such a way that the pipes arranged along the flow direction of the extinguishing fluid, i.e. in the fluid direction, may be selected for one or a plurality in front of or for one or a plurality of pipes behind the pipe under consideration. Thus, the pipe geometry values of the pipe immediately following the pipe actually under consideration—viewed along the fluid direction—or of the preceding one may be used or the pipe geometry values of pipes which are arranged along the fluid direction several pipes spaced several pipes away in front of or behind the pipe under consideration.

In a preferred embodiment, the minimum nominal width is estimated in particular. The nominal width is initialized with the calculated minimum nominal width. During adjustment, the nominal width is then continuously increased (and not reduced). This has the advantage that a fall below the minimum value cannot occur. Additionally or alternatively, a maximum nominal width may also be estimated. In this case, a calculated maximum nominal width may also be initialized. This nominal width may then be then reduced.

In accordance with a further embodiment, the approximation of the initial pipe geometry for each of the plurality of pipes further comprises a classifying of the corresponding pipe.

The pipes may initially be classified in order to be able to carry out an approximation and an adjustment of the pipe geometry as precisely as possible and to ensure the reliability of the present method. The approximation and adjustment of the pipe geometry is then performed depending on the classification. In the context of the invention, such a classification may particularly encompass determining whether the respective pipe has already been approximated and/or its geometry has already been adjusted, or whether the pipe comprises a fitting, an end piece, one or a plurality of extinguishing fluid outlets, or a T-piece or the like. These factors are included in the approximation of the individual pipe geometry values based on a hydraulic calculation to ensure that the behavior of the extinguishing fluid is accurately reflected at these locations.

In a preferred embodiment, the method further comprises specifying a predetermined number of iterations, wherein, if the predetermined number of iterations is exceeded, the adjustment of the initial pipe geometry is carried out at least partially based on at least one other fluid parameter. In a further development of this embodiment, at least one other fluid parameter is indicative of a flow regime within at least one tube of the plurality of pipes.

In some cases, it may happen that the approximation of the pipe geometries on the basis of only one fluid parameter fails to converge. In order to prevent one iteration after another from being performed in such a case without a result being possible, a measure is established which provides for the adjustment of the pipe geometry to determine the pipe geometry taking into account other factors, in particular, at least one other fluid parameter. In some embodiments, the at least one other fluid parameter comprises a parameter that is indicative of the flow regime by the pipe to be adjusted and/or the pipe network. This allows the flow regime to be entered as further input for the adjustment so that variables that are more known can be used here.

In order to determine such a further fluid parameter, in particular the parameters speed, mass flows and/or density of the different phases of the (multiphase and/or multicomponent) extinguishing fluid together with certain pipe characteristics, such as cross-section and friction coefficients may be taken into account. These parameters may then be used to generate other various helpful fluid parameters, which, for their part, allow a statement about the flow regime within the pipe and/or pipe network to be made. Examples of such parameters can be, for example, surface velocities, the ratio of fluid to inner pipe wall, the ratio of one fluid component to the other and/or the ratio of pressure losses in the individual phases.

These further fluid parameters may be evaluated in particular by a comparison with predetermined limit values. Here, these limit values may correspond, in particular, to literature values and/or measured values. If the values of at least one other fluid parameter deviate from the limit values, this means that an adjustment of the initial pipe geometry, in particular the cross-section, must be performed. In turn, this causes a change in the values of the other fluid parameter by changing the geometry within the pipe network.

This additional input makes the calculation even more precise while simultaneously reducing the risk of wasting processing resources (due to infinite iteration loops). This results in a method that allows the pipe geometry to be adjusted as efficiently as possible and, at the same time, in a precise manner.

In another preferred embodiment, the method furthermore comprises specifying a maximum number of iterations and aborting the method if the maximum number of iterations is exceeded.

Preferably, an upper limit of iterations may be specified. If no convergence of the values of the operating parameter at the appropriate target value has been achieved at this point in time, the modeling is aborted. In this case, it can be assumed that the modeling has an inherent error value that prevents a convergence. In some embodiments, an error can be displayed on a display element.

In some embodiments, nominal widths are also output for all pipes. This means that nominal widths will be output for both the completed as well as the uncompleted pipes. In particular, these uncompleted nominal widths can be output on the basis of the minimum nominal widths. This may result in a model of the pipe network being provided even if no convergence has been reached. In addition, if the user is given an indication that this is a non-optimized model, the user can decide for himself/herself whether he/she still wants to work with the model, in particular, if he/she would like to set up the pipe network on the basis of the model or not.

In accordance with a further embodiment, the method further comprises controlling of a device for manufacturing one or more of the plurality of pipes in accordance with the modeling.

Such devices usually comprise units for the physical shaping of the pipes in accordance with modeled specifications. For example, in accordance with a model, it may be specified that a pipe should have a certain predetermined diameter at a certain length, as well as a certain thickness in order to ensure, on the one hand, that the necessary amount of fluid at the necessary pressure can be conveyed through the pipe, but the pipe also has a necessary stability on the other hand.

Devices for the provision of pipes for a pipe network, in particular, a pipe network for conveying an extinguishing fluid, are therefore set up to manufacture corresponding pipes on the basis of certain specifications, which can then be integrated into an already existing pipe network or one that is still to be set up for a fire protection area for the purpose of fire protection.

According to the invention, the model provided for this purpose is created by the method according to the invention. The device for manufacturing is thus set up to manufacture the pipes of the pipe network based on the completed model. The pipes manufactured by the device may then be installed at a destination representing the fire protection area to be protected by the pipe network and then be connected to a pipe network in accordance with the model. This installation may be performed manually or automatically. In some embodiments, the model may be used to create a kind of “installation card” for an installer, which indicates at what point in the fire protection area and, thus, at what point of the pipe network, which pipe is to be arranged. In some embodiments, the device for manufacture may in particular also be arranged for marking the individual pipes manufactured by them accordingly, for example, by means of a barcode or a numbering so that an installer and/or installation robot can determine, based on the marking, at which point of the pipe network which pipe is to be arranged.

Devices and methods for the manufacturing of one or a plurality of pipes are already known from the prior art. For example, EP 3 550 195, WO 2018/109067 and EP 2 959 986 show different aspects of the manufacturing process as well as corresponding devices for the manufacturing of pipe elements and pipe arrangements for conveying fluids through a pipe network.

According to the invention, the completed model of the pipe network provided after completion may be used as input for a manufacturing process. In some embodiments, the model is first established and corresponding final calculations are performed to complete the model. This means that the approximated and adjusted pipes are conclusively calculated once again. This calculation may be manually initiated by a user. Additionally or alternatively, the calculation may also be started automatically once all the pipes have been approximated and adjusted.

For use for a manufacturing process, the model may particularly be transmitted to a corresponding device for manufacturing by means of a physical medium, such as a USB stick, a memory card or the like. Additionally or alternatively, the model may also be transmitted to the device for manufacturing over a network and/or a different signal connection, wireless or wired. The transmission may comprise a check by the user and/or recalculations that precede the manufacturing process.

In response to obtaining the model, the device for manufacturing then initiates a manufacturing of the individual pipes according to the specifications provided by the model. The manufacturing process may also encompass an indexing of the individual pipes indicating at which point in the pipe network the pipe is to be placed. The use of the pipe network model for the manufacturing of the pipes allows for a fully and holistically planned pipe network to be manufactured.

It is preferable that the method further comprises creating a graphical user interface for display on a display element, wherein the graphical user interface comprises a graphical representation of a pipe network model based on the modeling and comprises providing a user interface to enable a user to interact with the pipe network model.

In some embodiments, the method further comprises creating a graphical representation of the model of the pipe network. This graphical representation may particularly be provided as part of a graphical user interface that is displayed to the user on a display element.

The graphical user interface may be implemented in different ways. In particular, the graphical user interface may be an add-on to the creator of the model. Additionally or alternatively, the graphical user interface may also be a display at the manufacturer of the pipes or at the operator or end-user of the pipe network. Further configurations of the graphical user interface are conceivable.

In some embodiments, the graphical representation covers the entire pipe network. This means that the full pipe network model is displayed. Additionally or alternatively, the graphical representation may comprise parts of the pipe network model and/or individual parameters for individual pipes and/or the operating parameters of the system, the fluid parameters within the pipe network, the fluid values for the extinguishing fluid within certain pipes or the like.

The model of the pipe network may therefore particularly be displayed as a graphical representation of the actual architecture of the pipes. Additionally or alternatively, a graphical representation of the model may also be viewed as a tabular representation of the individual values for the individual pipes, with or without specifying their position.

The advantage of such an embodiment is such that the user can interact with the graphical representation of the model. In this context, an interaction may particularly be understood to correspond to a visual assessment of the model. Additionally or alternatively, the user may also interact with the model by adjusting one or a plurality of parameters and/or their values. In some embodiments, the interaction may also be understood as meaning that the user cannot make any changes to the given model. In this case, an interaction may also be understood as a selection and/or zooming in and/or zooming out and/or adding elements and/or information or the like.

In accordance with another preferred embodiment, the approximation and/or adjustment of the pipe geometry of each of the pipes of the pipe network is based on one or a plurality of input values, wherein these input values comprise one or more of: Information about a room geometry of a room in which the pipe network is arranged and/or information about the extinguishing fluid conveyed through the pipe network and/or information about reference values and/or guidelines to be adhered to for the pipe network and/or additional information that is indicative of a user preference for approximation and/or adjustment.

According to the invention, the initial approximation and/or the corresponding adjustment of the tube geometry, particularly the nominal values, may occur on the basis of a very wide variety of different factors. In one embodiment, the spatial geometry of the room served by the pipe network may be used as input. In this case, factors such as the ceiling height of the room, possible obstacles that prevent the pipe network from running at a certain point, such as doors and windows, and/or restrictions on how far the pipe network may protrude into the room, may be taken into account.

Additionally or alternatively, information about the extinguishing fluid may also be used to improve the model. Such information may include, for example, the amount of the extinguishing fluid, its composition, pressure, temperature or the like. In some embodiments, additives to the extinguishing fluid may also be used to improve the model.

Additionally or alternatively, the input can also comprise reference values as prescribed in certain specifications and/or guidelines. This information allows to improve the definition of the boundary conditions during the hydraulic calculation for estimation and to take into account the safety-relevant aspects of the design of the pipe network. Other inputs are also conceivable.

Additionally or alternatively, the pipe network can also be estimated on the basis of additional information, which is indicative of a user preference. This additional information may be based in particular on the economic considerations of the user and can therefore be preferred by the user. For example, it may be advantageous to use pipes with diameters that are as uniform as possible, which can be ordered in greater length and then installed. Such an arrangement saves installation effort and reduces the number of fittings that need to be implemented within the pipe network.

In another embodiment, the pipe network comprises a plurality of extinguishing fluid outlets. The method further comprises determining an outlet geometry for each of the plurality of extinguishing fluid outlets based on the pipe geometry of the corresponding pipe at which the corresponding extinguishing fluid outlet is arranged.

In some embodiments, the method may also be used to estimate the extinguishing fluid outlets. This allows for a uniform design of extinguishing fluid outlets and the corresponding pipes to which the outlets are connected. In this way, the extinguishing fluid outlet geometry and, in particular, the diameter, the length and the like, of the extinguishing fluid outlet may be better adapted to the corresponding extinguishing fluid situation in the respective pipe. This allows for an improved, holistic design as well as an optimized amount of the extinguishing agent at the application point.

In accordance with a further embodiment, the method further comprises an identification of at least one hydraulic characteristic.

In some embodiments, a hydraulic calculation is carried out after the approximation of the pipe network as a whole. This hydraulic calculation makes it possible to determine one or a plurality of hydraulic parameters. Under a hydraulic characteristic, here in particular, parameters are summarized, which allow a statement about the fluid dynamics of the extinguishing fluid within the pipe network to be made.

In some embodiments, the hydraulic characteristic may particularly comprise the throughput as well as the flow rate of the extinguishing fluid. These values may particularly be determined depending on external factors such as temperature or the like. One or a plurality of hydraulic parameters allow for a simpler and more direct possibility of state evaluation and determination of functionality.

In a further preferred embodiment, the extinguishing fluid comprises a multiphase extinguishing fluid. Multiphase extinguishing fluids, such as perfluoro-2-methyl-3-pentanone and/or heptaflourpropane are particularly preferred. In a modification of this embodiment, the pipe network further comprises one or more branches, wherein the method entails approximating a phase distribution at the one or more branches.

In the context of the invention, a multiphase extinguishing fluid may particularly correspond to an extinguishing fluid which has a plurality of phases (liquid/solid, liquid/gaseous, liquid/solid/gaseous). In a particularly preferred embodiment, the phases are liquid and gaseous. These different phases of the extinguishing fluid may lead to a phase distribution at junctions and/or splittings. In some embodiments, the phase distribution may particularly comprise a gas phase distribution.

In order to obtain the most accurate model of the pipe network, it is necessary to include the phase distribution in these places into the approximation. Here, it is assumed that the liquid and the gaseous phases of an extinguishing fluid do not distribute evenly at a side branch. This means that depending on whether the extinguishing fluid flows sideways past a head T-piece or flows straight past a side T-piece, the composition of the phases changes. Usually, the liquid content increases along the pipe through which the extinguishing fluid is conveyed and the gas content increases for the branched pipe. These changes can be derived on the basis of empirically derived equations.

In a further embodiment, the extinguishing fluid comprises a multicomponent extinguishing fluid, wherein the multicomponent extinguishing fluid may also be provided as a multiphase multicomponent extinguishing fluid. Hereby, each of the plurality of components can be provided in a particular phase, i.e. the first component may be gaseous and the second component may be a liquid, or one or both components may be provided in a plurality of phases. Thus, for example, the first component may be both liquid and gaseous, wherein the gas is preferably dissolved in the liquid and a second component can only be gaseous or also even both gaseous as well as liquid. In other embodiments, the components may also be present in other phase combinations.

In some embodiments, it is advantageous that the extinguishing fluid—in addition or alternatively to the multiphase extinguishing fluid—comprises or is provided as a multicomponent extinguishing fluid. Hereby, it is particularly preferred to add a gas to the extinguishing fluid. In the event of a fire, this gas may then spread out after opening the pipe network and thus distribute the extinguishing fluid as efficiently as possible. For this purpose, this gas should preferably be non-toxic to the human body, be well mixed with liquid components, and have the necessary expansion characteristic to allow a corresponding distribution of the extinguishing fluid. Suitable gases include, for example, nitrogen, helium, argon and other gases with comparable characteristics.

The fact that the extinguishing fluid is a multicomponent extinguishing fluid should also be included in the adjustment of the pipe geometry. This means that the fluid values are determined with regard to the multicomponent characteristics and compared with corresponding target values. This allows for the pipes to be determined with even greater precision.

In yet another embodiment, the method furthermore entails checking an initial specification of the pipe network, wherein the modeling is aborted in the event of an error.

In some embodiments, before starting the iterative process for modeling the pipe network, it is initially assessed whether the initially specified values for the pipe network are allowed, i.e. are leading to an acceptable result.

This assessment may particularly encompass checking whether the required pressures at the extinguishing fluid outlets are complied with at all, and, in particular, at the nozzles, as well as checking the minimum pressures within the individual pipes. These specifications may hereby be taken from the relevant safety specifications and guidelines.

Furthermore, the assessment can encompass checking that the specifications relating to the regime for which the extinguishing fluid flow can be determined and, thus, for which the pipe geometry can be estimated, are met at every point within the pipe. This means that it is checked whether the gas, liquid or solid components and characteristics are within certain limits and thus form the required regime. If this were not the case, this would lead to inaccuracies in the calculation. In order to verify that the regime is being adhered to, the method includes a calculation that allows to assess specific parameters and equations regularly. This assessment is preferably carried out after each calculation step. The regime for the extinguishing fluid depends in particular on the phase composition of the extinguishing fluid, its superficial velocities and its material values.

Furthermore, it is verified that the quantities diverted at junctions from the main line do not exceed or fall below certain limits, as this would also lead to an inaccuracy of the modeling. It is also assessed whether sufficient (not too many) extinguishing fluid outlets are connected so that the extinguishing fluid can be transferred quickly and reliably into the room.

Finally, the system assesses if all safety guidelines and approval criteria relevant to the pipe network model have been met. If this is the case, the method terminates the process and indicates that the system is in order. This checking can be performed manually. In addition or as an alternative, the system can also be set up to initiate the check automatically.

In another aspect, the invention relates to a system for modeling a pipe network for conveying an extinguishing fluid, comprising a processor, which is configured to approximate at least one operational parameter of the pipe network and an initial pipe geometry for each of a plurality of pipes of the pipe network based on at least one fluid parameter within the pipe network, to determine at least one fluid value of the extinguishing fluid based on the approximation for each of the plurality of pipes, to compare the at least one fluid value with a target value, to adjust the initial pipe geometry for at least one pipe from the plurality of pipes based on the comparison, and to adjust at least one operation parameter of the pipe network, wherein the processor is set up to carry out the steps iteratively.

In accordance with a preferred embodiment of the system, the system may further comprise a display element that is configured to provide a graphical user interface, wherein the graphical user interface is a graphical representation of a pipe network model based on the modeling, and a user interface to enable a user to interact with the pipe network model.

In another embodiment, the system includes a control that is set up to control a device for manufacturing one or more of the plurality of pipes in accordance with the modeling.

In an even further aspect, the invention relates to a computer program with program code means, which cause a processor to execute the method according to the invention. In this way, the method may be implemented using one or a plurality of processors on one or a plurality of computers.

### BRIEF DESCRIPTION OF THE DRAWINGS

In the following, the invention will be explained in further detail on the basis of the exemplary embodiment as illustrated in the figures. The figures show:

FIG. 1a flowchart of a method for modeling a nozzle pipe network for conveying an extinguishing fluid in accordance with a preferred embodiment, and

FIG. 2a schematic representation of a system for modeling a nozzle pipe network for conveying an extinguishing fluid in accordance with a preferred embodiment.

### MODE(S) FOR CARRYING OUT THE INVENTION

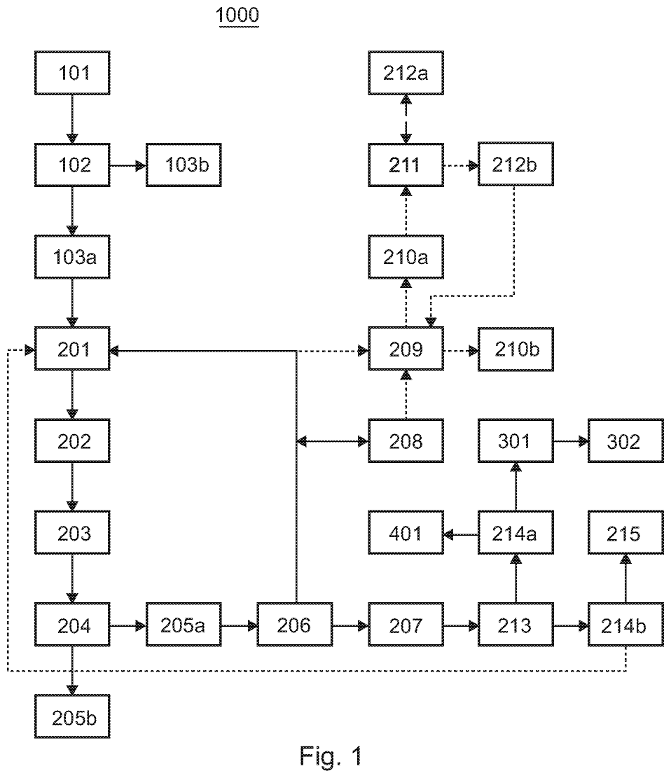

FIG. 1 schematically shows a flowchart illustrating the steps of a method 1000, which can be used to estimate the geometry of one or a plurality of pipes in a nozzle pipe network for conveying an extinguishing fluid from an extinguishing fluid supply to one or a plurality of extinguishing fluid outlets, which may particularly be designed as nozzles. In the specific embodiment of FIG. 1, the nominal widths of the individual pipes of the pipe network are approximated by means of the method.

By approximating the nominal widths of the individual pipes, the nozzle pipe network can be determined holistically so that the structure and course of the nozzle pipe network can be modeled and assessed even before the start of the manufacturing and construction process. After assessing and approving the model, the model can then be used to control a manufacturing process.

For this purpose, the method is initialized at step 101. During this initialization, the initial parameters of the nozzle pipe network to be modeled must first be collected. In the specific exemplary embodiment of FIG. 1, these initial parameters particularly comprise the pipe isometry, the amount of the extinguishing fluid to be conveyed through the nozzle pipe network, the filling quantity of the extinguishing fluid and the filling pressure within the individual cylinder, the (desired) outlet period—that is, a specification of how quickly the extinguishing fluid should be output—as well as information regarding the individual nozzles within the nozzle pipe network, such as the amount to be output and the expected outlet pressure, their position or the like. Furthermore, the initialization comprises an initial approximation of at least one operating parameter of the nozzle pipe network. In the embodiment of FIG. 1, this operating parameter comprises the operating pressure at the extinguishing fluid supply. In the particular embodiment, the initialization also comprises the input of environmental information, i.e. information about the environment of the nozzle pipe network, such as size, temperature, humidity, density or the like of the room in which the nozzle pipe network is arranged.

Based on this information, at step 102, the initial specification of the pipe network is assessed. In other words, it is tested whether the initial parameters are outputting an error or not. This can lead to an error-free check of the initial parameters and thus the initial specification of the nozzle pipe network or to an error identification when checking the initial specification of the nozzle pipe network.

At step 103b, an error identification of the initial specification occurs. In the specific embodiment of FIG. 1, this leads to the method for modeling the nozzle pipe network being aborted and an error message being output to the user. In particular, here, the user may be given an indication of the possible cause of the error.

At step 103a, the check results in an error-free state of the nozzle pipe network with respect to the initial specification. This is an indication that the approximation of the pipe geometry, in particular, the nominal width of the individual pipes, can be used. In this case, the method progresses to step 201.

At step 201, the approximation and adjustment of the nominal widths of the individual pipes are initialized based on a hydraulic calculation. In the specific embodiment of FIG. 1, the approximation and adjustment is performed for each pipe within the nozzle pipe network, wherein the pipe that is started with is the one closest to the extinguishing fluid supply and whereby the approximation and adjustment gradually progresses along the pipe network in the direction of the extinguishing fluid outlet(s). The following steps are carried out for each individual pipe, meaning an estimation is made pipe by pipe within the nozzle pipe network.

For this purpose, at step 202, the pipe to be approximated and adjusted is initially classified. In the specific embodiment of FIG. 1, this classification comprises an assessment of whether an approximation for this pipe has already taken place—this can be the case in a second or any further iteration—and/or whether the nominal width has already been adjusted. In addition, the classification encompasses determining whether the pipe to be estimated comprises a fitting or nozzle, is part of a junction and/or comprises a closed end.

Based on the classification, the hydraulic calculation is then adjusted. In the specific embodiment of FIG. 1 this means that, in the event that it is found that the pipe comprises a fitting, a pressure loss of the inner tube pressure due to the fitting is included in the calculation. If it is determined that the pipe inlet is at a junction, the hydraulic calculation includes the pressure loss at the junction and the phase distribution of a multiphase multicomponent extinguishing fluid. In the event that it is found that the pipe comprises a nozzle or an end piece, the method must additionally assess if the estimate has reached one end of the nozzle pipe network starting from the extinguishing fluid supply.

Taking into account the classification, the nominal width of the pipe is then initially estimated at step 203, i.e. is approximated. At step 204, this approximation is then checked. In the embodiment in accordance with FIG. 1, this means that it is assessed whether the initial nominal width moves within an upper limit value, which specifies a maximum nominal width, and a lower limit value, which specifies a minimum nominal width.

If this assessment shows that the initial nominal width is outside these limit values, an error identification is output at step 205b. This error identification may include an error indication output to a user. The error indication can be haptic and/or auditory and/or visual.

If this assessment shows that the initial nominal width is within the limit values, this nominal width is used at step 205a to calculate at least one fluid value of the extinguishing fluid for the corresponding pipe. The fluid values thus determined may then be stored in a memory. In the embodiment of FIG. 1, the fluid values comprise, in particular, values for the density, the gas content, the mass and the pressure or the pressure loss of the extinguishing fluid along the corresponding pipe. The calculation of the pressure loss makes it possible to determine, in particular, the pressure of the extinguishing fluid at the end of the pipe.

At step 206, this pressure of the extinguishing fluid at the end of the pipe is compared as a fluid value with a target value. In the specific embodiment of FIG. 1, the target value with which the pressure is compared corresponds to the target pressure of the nozzle.

If the pressure is below the target pressure, the method proceeds to step 208. At step 208, the method returns to the pipe that lies in front of the pipe from the extinguishing fluid supply for which nominal width the fluid value was compared with the target value at step 206 and increases the nominal width of this pipe. It is then assessed whether the increase in the nominal width of the previous pipe is permissible. If this is the case, the method immediately returns to step 201 and restarts the estimation for the following pipe as described above. Even if, in the specific embodiment of FIG. 1, the method returns to the previous pipe, in other embodiments, the nominal width of the pipe under consideration at step 206 may also be adjusted and, may, particularly be increased. In other embodiments, the nominal widths of further subsequent or preceding pipes may also be adjusted, particularly increased. The adjustment method is analogous in all cases.

If the nominal width increase is not permitted, at step 209 it is assessed whether or not the increased nominal width exceeds a nominal width maximum value or not. If the nominal width maximum value is exceeded, an error identification and an output of an error indication take place at step 210b.

If the nominal width maximum value is not exceeded, the approximation at step 210a returns to the first pipe of the nozzle pipe network and assesses at step 211 whether the nominal width of this first pipe during the corresponding iteration in the nozzle pipe network as a whole has already been increased or not.

If this is the case, the method proceeds at step 212a to the pipe which follows the first pipe starting from the extinguishing fluid supply and assesses whether its nominal width has already been increased. Steps 211 and 212a are performed for the successive pipes until a pipe has been identified whose nominal width has not yet been increased in the iteration cycle. In this case, at step 212b, the nominal width is increased and the method returns to step 209 and assesses whether the nominal width increase is admissible. This cycle is repeated as often as needed until the method detects an acceptable nominal width increase and can thus return to step 201.

If the pressure is above the target pressure, the nominal width determined is accepted and the method begins for the subsequent pipe. The steps 201 to 206 are then carried out for this pipe. Hereby, the determined values of the approximate pipe are used as inlet values for the connection to the following pipe. In this way, each pipe of the nozzle pipe network is approximated, so steps 201 to 206 are carried out for all pipes, starting from the extinguishing fluid supply to the end pieces of the nozzle pipe network.

If the nominal widths of all pipes have been estimated and adjusted in accordance with steps 201 to 206, the method proceeds to step 207 in which at least one operating parameter is recalculated on the basis of the adjustment. In the embodiment in accordance with to FIG. 1, in particular, the operating pressure of the pipe network is recalculated.

At step 213, a convergence assessment for operating pressure is then carried out. Thus, it is assessed whether the newly calculated value for the operating pressure and the previous value converge. If the convergence assessment is positive, the calculated values converge so the pipe network model is passed to a display element at step 214a.

If the convergence assessment is negative, at step 214b, it is assessed whether or not the number of iterations for approximating the nominal widths of the pipes has already reached a maximum number. If the maximum number is exceeded, an error identification is performed at step 215 and an error indication is output. Hereby, the iteration method is then aborted.

If the maximum number of iterations has not yet been reached, the method starts with step 201 for all pipes from the front. Thus, a new iteration is started in which all nominal widths for all pipes of the pipe network as described above are re-estimated on the basis of the previously newly determined operating parameter—i.e. the newly determined operating pressure.

At step 301, the display element receives the model of the pipe network and creates a graphical representation of the model. At step 302, the graphical display is then displayed on the display element and can thus be assessed by the user.

At step 401, the model of the pipe network is also used to initiate a device for the manufacture of one or a plurality of pipes for the pipe network in accordance with the modeling. In this case, the control can occur, in particular, in response to a manual confirmation of the user, who has previously visually assessed the model on the display element and, if necessary, has made changes. Alternatively, the control can also occur automatically in direct response to the positive convergence assessment.

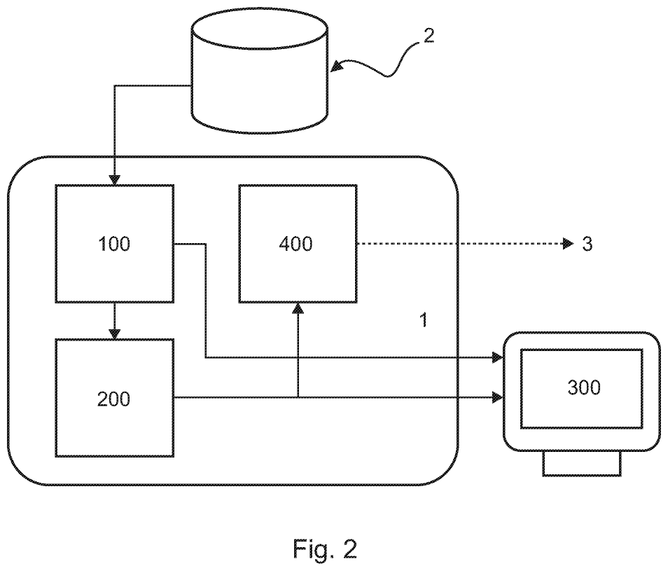

FIG. 2 schematically shows a system 1 for modeling a pipe network, in particular, a nozzle pipe network. The system comprises one or more processors by means of which an input unit 100, a calculation unit 200 and a control unit 400 are implemented. The calculation unit 200 is set up for the approximation and adjustment of the pipe geometry, in particular, the nominal width, of the individual pipes. Furthermore, the system 1 communicates with a database 2, a device for manufacturing at least one pipe of the pipe network 3, and a display unit 300 for displaying the pipe network model.

The input unit 100 initially allows, as part of the initialization, the collection of the initial parameters of the nozzle pipe network to be modeled for further calculation and accepts, during the initialization, the approximation of at least one operating parameter of the nozzle pipe network, which, in the embodiment of the FIG. 2, comprises the operating pressure at the extinguishing fluid supply, or calculates this. This can occur, in particular, by reading empirical values from database 2 and by estimating, by the input unit 100, the initial parameter and/or at least one operating parameter on the basis of the empirical values.

Furthermore, the input unit 100 is configured to receive input values, such as information about the room geometry, about the extinguishing fluid, about reference values and/or guidelines, as well as about possible user preferences. In the specific embodiment of FIG. 2, the input unit 100 is particularly configured to receive environmental information, i.e. information about the environment of the nozzle pipe network, such as the size of the network, temperature, humidity, density or the like of the room in which the nozzle pipe network is arranged. Furthermore, the input unit 100 may be configured to receive a user input that is indicative of the amount of extinguishing agent to be introduced per unit of time, i.e. per application time. Additionally or alternatively, the amount of extinguishing agent to be applied can also be determined automatically on the basis of the size and temperature of the room.

The input unit 100 is configured to assess the initial specification of the pipe network. In the event of an error identification of the initial specification, the estimation method is aborted and the input unit 100 causes the output of an error message. The error message can be haptic and/or auditory and/or visual and can comprise an indication of the possible cause of the error.

If the input unit 100 cannot identify an error with respect to the initial specification, the input unit 100 is set up to pass the initial parameters, i.e. all values to be used for the calculation, to the calculation unit 200.

The calculation unit 200 is set up to approximate and adjust the pipe geometry, particularly the nominal widths of the individual pipes, by means of a hydraulic calculation. The corresponding approximation (and adjustment) is carried out for each pipe within the nozzle pipe network. The calculation unit 200 is configured to start with the pipe closest to the extinguishing fluid supply and gradually progress along the pipe network in the direction of the one or more of the extinguishing fluid outlets until all pipe geometry values are determined.

For this purpose, the calculation unit 200 is configured to initially classify the respective pipe and to adjust the hydraulic calculation for estimation accordingly. This means that factors such as junctions, end pieces or the like are included in the calculation.

The calculation unit 200 is furthermore configured to approximate and adjust the pipe geometry, i.e. the pipe geometry values, of the individual pipes of the nozzle pipe network as in connection with FIG. 1. For this purpose, the calculation unit 200 begins with the estimation of the pipe, which follows the extinguishing fluid supply and progresses gradually from the extinguishing fluid supply to the ends of the nozzle pipe network. Hereby, the calculation unit 200 is configured to, each time the process has reached an end piece, i.e. at one end of the pipe network, assess whether the pipe geometry values of all pipes have been determined or whether further branches are to be considered.

Hereby, the calculation unit 200 is, particularly configured to approximate both the geometries of the individual pipes as well as the model of the nozzle pipe network as a whole iteratively. This means, on the one hand, that the values of the individual pipes are adjusted until the desired target values are reached and, on the other hand, that, after approximating all pipes, the nozzle pipe network is iteratively improved by calculating an operating parameter of the nozzle network for the iteratively determined pipe geometry values long enough until the calculation of the operating parameter values converges at a target value. In this case, a maximum number of iterations is specified for the system 1. If this number of operating parameter values do not converge at the target value, the method is aborted and must be restarted.

If the convergence assessment is positive, the pipe network model is passed on to the display element 300. The display element 300 is configured to receive the model of the pipe network and to create a graphical representation of the model. In addition, the display element 300 is configured to display this graphical representation. Based on this display, the user may then visually assess the model.

The display element 300 may also be configured to generate and display a graphical representation of the error indications and/or the reasons for aborting. In general, the display element 300 is used to visually inform the user about the modeling.

The calculation unit 200 and/or the display element 300 is/are also configured to output the model of the nozzle pipe network to the control unit 400. The control unit 400 is configured to control a device for manufacturing one or a plurality of pipes for the pipe network in accordance with the modeling. This control may occur in response to a manual confirmation of the user who has previously visually assessed the model on the display element and made changes, if necessary. Additionally or alternatively, the control may also occur automatically in response to the positive convergence assessment.

The preceding description of the figures is to be understood as an example and does not limit the invention to the embodiments described above. Further embodiments of the invention are apparent to the person skilled in the art from the description of the preferred embodiments. In this case, this description is to be understood in such a way that the preferred embodiments of the method are also simultaneously preferred embodiments of the system and the preferred embodiments of the system are simultaneously preferred embodiments of the method.

### LIST OF UTILIZED REFERENCE NUMBERS

1 System for modeling
100 Input unit
200 Processing unit
300 Display unit
400 Control unit
2 Database
3 Device for manufacturing one or more pipes of the pipe network
1000 Method for modeling a pipe network
101 Initialization of the system
102 Checking an initial specification of the pipe network
103a Error-free checking of an initial specification of the pipe network
103b Error identification when checking an initial specification of the pipe network
201 Initializing the approximation and adjustment of the nominal widths of the individual pipes
202 Classifying the pipe to be approximated and adjusted
203 Approximating an initial pipe geometry for each pipe from a plurality of pipes
204 Checking the approximation
205a Determining at least one fluid value of the extinguishing fluid based on the approximation for the corresponding pipe
205b Error identification when checking the approximation
206 Comparing the fluid value with a target value and adjusting the pipe geometry and transition to the next pipe
207 Adjusting the at least one operating parameter of the pipe network after determining all pipe geometry values
208 Transition to previous pipe when the limit value is exceeded
209 Assessing the pipe geometry
210a Returning to the first pipe of the pipe network when not exceeding the maximum pipe geometry value
210b Error identification when overwriting a pipe geometry maximum value and output of an error indication
211 Checking a previous pipe geometry increase of the first pipe
212a Progressing to the following pipe in the case of prior pipe geometry increase and checking
212b Enlarge the pipe geometry in the absence of a previous pipe geometry increase
213 Convergence assessment for the operating parameters or
214a Output of the pipe model to a display element in the case of a positive convergence assessment
214b Assessing the number of iterations in the case of a negative convergence assessment
215 Error identification for negative convergence after N iterations and output of an error indication and aborting the method
301 Generating a graphical representation of a pipe network model in accordance with the modeling
302 Displaying a graphical representation of a pipe network model in accordance with the modeling
401 Controlling a device for manufacturing one or a plurality of pipes of the pipe network in accordance with the modeling

1. A method for modeling a pipe network for the conveying an extinguishing fluid, characterized by the steps of:
i) approximating at least one operating parameter of the pipe network and an initial pipe geometry for each of a plurality of pipes of the pipe network based on at least one fluid parameter within the pipe network,
ii) determining at least one fluid value of the extinguishing fluid based on the approximating for each of the plurality of pipes,
iii) comparing at least one fluid value with a target value,
iv) adjusting the initial pipe geometry for at least one pipe from the plurality of pipes based on the comparing, and
v) adjusting at least one operating parameter of the pipe network, wherein the method comprises multiple iterations of steps i) to v).

2. The method according to claim 1, wherein, during each iteration, each of the pipes of the pipe network is approximated and adjusted one after the other along the flow direction of the extinguishing fluid.

3. The method according to claim 1, further comprising:
specifying at least one pipe geometry limit value for at least one pipe geometry parameter of each of the pipes from the plurality of pipes,
comparing the pipe geometry limit value with a pipe geometry value approximated for the corresponding pipe geometry parameter for the corresponding pipe, and,
if it is determined that the value exceeds and/or undercuts the limit value:
aborting the adjusting of the pipe geometry for the corresponding pipe.

4. The method according to claim 3, further comprising, if it is determined that the value exceeds and/or undercuts the limit value:
adjusting the pipe geometry of another pipe, which is arranged in the flow direction of the extinguishing fluid in front of or behind the corresponding pipe.

5. The method according to claim 1, wherein the approximation of the initial pipe geometry for each of the plurality of pipes further comprises a classification of the corresponding pipe.

6. The method according to claim 1, further comprising:
specifying a predetermined number of iterations, wherein, if the specified number of iterations is exceeded, the adjustment of the initial pipe geometry is performed at least partially based on at least one other fluid parameter.

7. The method according to claim 6, wherein at least one other fluid parameter is indicative of a flow regime within at least one pipe of the plurality of pipes.

8. The method according to claim 1, further comprising:
specifying a maximum number of iterations, and
aborting the method if the maximum number of iterations is exceeded.

9. The method according to claim 1, further comprising:
controlling a device (3) for the manufacturing of one or a plurality of pipes in accordance with the modeling.

10. The method according to claim 1, further comprising:
generating a graphical user interface for display on a display element, wherein the graphical user interface includes a graphical representation of a pipe network model based on the modeling, and
providing a user interface to enable a user to interact with the pipe network model.

11. The method according to claim 1, wherein the approximating and/or adjusting of the pipe geometry of each of the pipes of the pipe network is furthermore based on one or a plurality of input values, wherein these input values comprise:
information about a spatial geometry of a room in which the pipe network is arranged, and/or
information about the extinguishing fluid that is conveyed through the pipe network, and/or
information about reference values and/or guidelines to be adhered to for the pipe network, and/or
additional information that is indicative of a user preference for the approximation and/or the adjustment.

12. The method according to claim 1, wherein the pipe network comprises a plurality of extinguishing fluid outlets and wherein the method furthermore comprises:
determining an outlet geometry for each of the plurality of extinguishing fluid outlets based on the pipe geometry of the corresponding pipe, at which the corresponding extinguishing fluid outlet is arranged.

13. The method according to claim 1, wherein the method further comprises determining at least one hydraulic parameter.

14. The method according to claim 1, wherein the extinguishing fluid comprises a multicomponent extinguishing fluid, in particular, perfluoro-2-methyl-3-pentanone and/or heptaflourpropane.

15. The method according to claim 14, wherein the pipe network further comprises one or more branches and wherein the method further comprises an approximating of a phase distribution at the one or more branches.

16. The method according to claim 1, wherein the extinguishing fluid comprises a multicomponent extinguishing fluid.

17. The method according to claim 1, wherein the method further comprises checking of an initial specification of the pipe network, and wherein the modeling is aborted in the event of an error.

18. A system for modeling a pipe network for conveying an extinguishing fluid, comprising a processor arranged for:
approximating at least one operating parameter of the pipe network and an initial pipe geometry for each of a plurality of pipes of the pipe network based on at least one fluid parameter within the pipe network,
determining at least one fluid value of the extinguishing fluid based on the approximating for each one of the plurality of pipes,
comparing at least one fluid value with a target value,
adjusting the initial pipe geometry for at least one pipe from the plurality of pipes based on the comparing, and
adjusting at least one operating parameter of the pipe network;
wherein the processor is arranged to perform multiple iterations of said steps.

19. The system according to claim 18, further comprising:
a display unit arranged for providing a graphical user interface, wherein the graphical user interface comprises a graphical representation of a pipe network model based on the modeling, and a user interface to enable a user to interact with the pipe network model.

20. The system according to claim 18, further comprising:
a control unit arranged for controlling a device for manufacturing one or more of the plurality of pipes in accordance with the modeling.

21. A computer program with program code means that cause a processor to perform the method according to claim 1.
